(19) United States
(12) Patent Application Publication
(10) Pub. No.: US 2012/0229155 A1
(43) Pub. Date: Sep. 13, 2012

(54) SEMICONDUCTOR INTEGRATED CIRCUIT, FAILURE DIAGNOSIS SYSTEM AND FAILURE DIAGNOSIS METHOD

(75) Inventors: Kenichi Anzou, Kanagawa-ken (JP); Chikako Tokunaga, Kanagawa-ken (JP); Shohei Morishima, Tokyo (JP)

(73) Assignee: KABUSHIKI KAISHA TOSHIBA, Tokyo (JP)

(21) Appl. No.: 13/227,106

(22) Filed: Sep. 7, 2011

(30) Foreign Application Priority Data
Mar. 8, 2011 (JP) 2011-050210

(51) Int. Cl. G01R 31/3187

(52) U.S. Cl. 324/750.3

(57) ABSTRACT

A semiconductor integrated circuit includes a memory containing multiple memory bits that store predetermined data placed in a first address direction and a second address direction. The semiconductor integrated circuit includes a BIST (Built-in Self-Test) circuit that diagnoses a failure of the memory.

The BIST circuit includes a BIST control circuit that controls a BIST on the memory. The BIST circuit includes a failure information table storing: a failed bit-cell position that is an address of a bit cell identified in the first address direction as a failed bit cell by the BIST conducted in the first address direction; the number of bit cell failures at the failed bit-cell position; and a failure overflow flag indicating whether the number of failures exceeds a predetermined upper value or not. The BIST circuit includes a result analyzer that outputs a BIST result obtained by the BIST on the memory.

### CROSS-REFERENCE TO RELATED APPLICATION

This application is based upon and claims the benefit of priority from the prior Japanese Patent Application No. 2011-050210, filed on Mar. 8, 2011, the entire contents of which are incorporated herein by reference.

### BACKGROUND

1. Field

Embodiments described herein relate generally to a failure diagnosis system diagnosing a memory device mounted in a semiconductor integrated circuit.

2. Background Art

In a method of detecting failures in a manufacturing test according to the related art, a built-in self-test (BIST) circuit is incorporated into a memory device mounted in a semiconductor integrated circuit.

Such failure detection methods include a comparator-type BIST in which written data and read data are compared to each other to decide the presence or absence of failures and a compressor-type BIST in which read results are compressed in a BIST circuit and the presence or absence of failures is decided based on the compression results.

According to such a failure detection method, a fail bit map indicating failed bit positions in a memory cell array can be generated to analyze failures.

In addition to relief analysis for improvement of manufacturing yields, another significant technique is a built-in self diagnosis (BISD) for collecting data for yield enhancement analysis.

In a failure analysis method for memory devices according to the related art, a fail bit map of overall memory is generated.

Unfortunately, in on-line information collection for each wafer or lot by means of BIST circuits during mass production, it takes a long time to fully generate a fail bit map, which is not suitable for practical use.

### BRIEF DESCRIPTION OF THE DRAWINGS

FIG. 1 is a diagram showing an example of the configuration of a failure analysis system 1000 according to a first embodiment;

FIG. 2 is a diagram showing an example of the configuration of a failure diagnosis system 2000 according to the second embodiment;

FIG. 3 is a diagram showing an example of the configuration of a failure diagnosis system 3000 according to the third embodiment;

FIG. 4 is a diagram showing an example of the configuration of the table mode switching circuit 502 in the BIST circuit 301b of FIG. 3; and

FIG. 5 is a flowchart showing an example of the flow of the failure diagnosis method according to the fourth embodiment.

### DETAILED DESCRIPTION

A semiconductor integrated circuit, according to an embodiment, includes a memory containing multiple memory bits that store predetermined data placed in a first address direction and a second address direction. The semiconductor integrated circuit includes a BIST (Built-in Self-Test) circuit that diagnoses a failure of the memory.

The BIST circuit includes a BIST control circuit that controls a BIST on the memory. The BIST circuit includes a failure information table storing: a failed bit-cell position that is an address of a bit cell identified in the first address direction as a failed bit cell by the BIST conducted in the first address direction; the number of bit cell failures at the failed bit-cell position; and a failure overflow flag indicating whether the number of failures exceeds a predetermined upper value or not. The BIST circuit includes a result analyzer that outputs a BIST result obtained by the BIST on the memory.

Embodiments will be described below in accordance with the accompanying drawings.

### First Embodiment

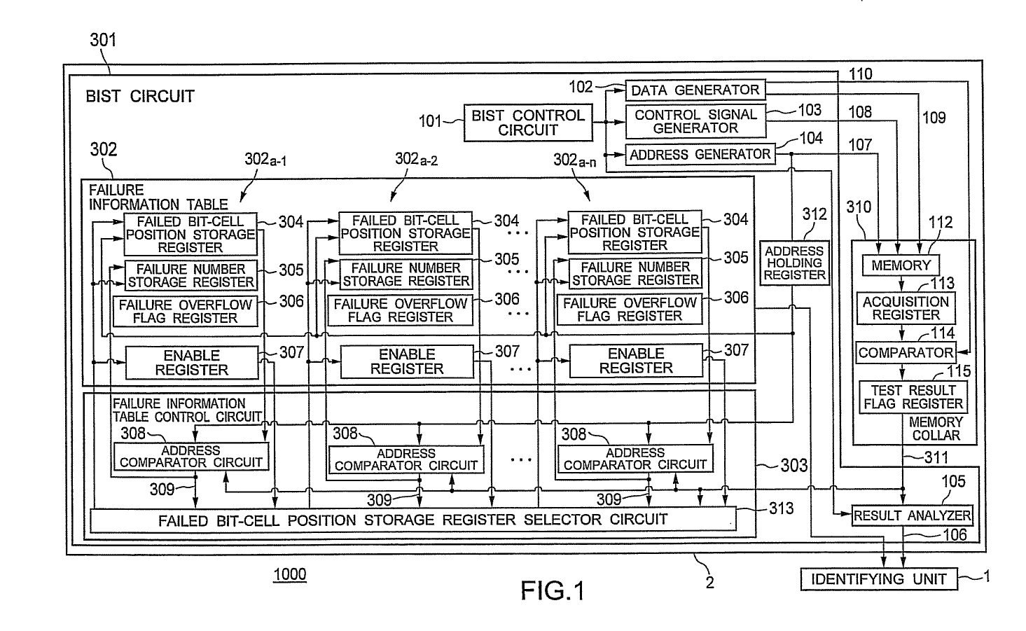

FIG. 1 shows an example of the configuration of a failure analysis system 1000 according to a first embodiment.

As shown in FIG. 1, the failure analysis system 1000 includes an identifying unit 1 and a semiconductor integrated circuit 2.

The semiconductor integrated circuit 2 includes: a built-in self-test (BIST) circuit 301 that diagnoses memory failures; and a memory collar 310.

The BIST circuit 301 includes a BIST control circuit 101, a data generator 102, a control signal generator 103, an address generator 104, a result analyzer 105, a failure information table 302, a failure information table control circuit 303, and an address holding register 312.

The BIST control circuit 101 controls the data generator 102, the control signal generator 103, and the address generator 104 to sequentially generate necessary signals, so that the BIST control circuit 101 controls a BIST on a memory 112.

The data generator 102 is controlled by the BIST control circuit 101 so as to generate and output written data 109. The control signal generator 103 is controlled by the BIST control circuit 101 so as to generate and output a control signal 108.

The address generator 104 is controlled by the BIST control circuit 101 so as to generate and output address data 107.

For example, the address data 107 includes column addresses and I/O bit positions in the column direction (first direction) of bit cells in the memory 112 and row addresses in the row direction (second direction) of the bit cells. Specifically, a bit cell in the memory 112 is specified by the row address, the column address, and the I/O bit position. In other words, the row address, the column address, and the I/O bit position constitute the address data 107 of the bit cell.

The memory collar 310 constitutes a block containing the memory 112, an acquisition register 113, a comparator 114, and a test result flag register 115. The acquisition register 113, the comparator 114, and the test result flag register 115 are logic elements required for test operations.

The memory 112 includes multiple memory bits that store predetermined data placed in the column direction (first address direction) and the row direction (second address direction).

The memory 112 receives the written data 109 generated in the data generator 102, the address data 107 generated in the address generator 104, and the control signal 108 generated in the control signal generator 103.

The memory 112 stores the written data 109 in response to the written data 109, the address data 107, and the control signal 108 for directing writing, and reads and outputs the stored data in response to the address data 107 and the control signal 108 for directing reading.

The acquisition register 113 stores data read from the memory bits of the memory 112 in response to the address data 107, and outputs the data.

The comparator 114 is controlled by the BIST circuit 101. The comparator 114 compares the read data outputted from the acquisition register 113 and a data expected value 110 generated in the data generator 102, and outputs the comparison result as test result flag 311 to the test result flag register 115.

The test result flag register 115 stores the test result flag 311 outputted from the comparator 114 and outputs the test result flag 311 to the result analyzer 105.

The result analyzer 105 outputs a BIST result obtained by the BIST on the memory. Specifically, the result analyzer 105 outputs a BIST result 106, which is obtained by checking the test on the tested memory 112, to the identifying unit 1 based on the test result flag 311.

In FIG. 1, the single memory collar 310 is provided for the single BIST circuit 301. Multiple memory collars 310 may be provided for the single BIST circuit 301.

For example, in the case where multiple memories 112 are tested by the single BIST circuit 301, the test result flag 311 for each of the memories 112 is inputted to the result analyzer 105. Then, the result analyzer 105 checks tests on all the tested memories 112 and outputs the BIST results 106, which are obtained by checking the tests, to the identifying unit 1.

As shown in FIG. 1, the failure information table 302 includes multiple (n) register groups 302a-0 to 302a-n.

The register groups 302a-0 to 302a-n each include a failed bit-cell position storage register 304, a failure number storage register 305, a failure overflow flag register 306, and an enable register 307.

The failed bit-cell position storage register 304 stores the failed bit-cell position (the row address or the column address and the I/O bit position) of a bit cell identified as a failure of the memory 112.

The failure number storage register 305 stores the number of bit cell failures (defects) at a certain failed bit-cell position.

The failure overflow flag register 306 stores a failure overflow flag FOVF that indicates whether the number of failures exceeds a predetermined upper limit value or not.

The enable register 307 stores shift enable that indicates whether data (failed bit-cell position) has been stored or not in the failed bit-cell position storage register 304 of the same register group. For example, the shift enable at “High” level (logic “1”) indicates that data has been stored, while shift enable at “Low” level (logic “0”) indicates that data has not been stored.

Moreover, the number of data sets storable in the failure information table 302 (i.e., the number of register groups) is n equivalent to the capacity of the failure information table 302 and is set at any number.

The failure information table 302 includes the multiple registers that respectively store the failed bit-cell position, the number of failures, and the failure overflow flag.

The failure information table control circuit 303 controls the operations of the failure information table 302. As shown in FIG. 1, the failure information table control circuit 303 includes address comparator circuits 308 and a failed bit-cell position storage register selector circuit 313.

The n address comparator circuits 308 in the failure information table control circuit 303 are provided for the respective register groups of the failure information table 302 (the n data sets stored in the failure information table 302).

The address comparator circuit 308 receives the test result flag 311 outputted from the memory collar 310 (comparator 114), an address outputted from the address holding register 312, and a failed bit-cell position outputted from the failed bit-cell position storage register 304.

In the case where the test result flag 311 has a value at “High” level (e.g., logic “1”), that is, the comparator 114 detects a failed bit cell, the address comparator circuit 308 compares a failed bit-cell position that is the bit cell address outputted from the address holding register 312 (for example, an address in the column direction (determined by a column address and an I/O bit position)) and a value stored in the failed bit-cell position storage register 304 (an address in the column direction).

Moreover, the address comparator circuit 308 outputs a matching signal 309 as the comparison result to the failed bit-cell position storage register selector circuit 313 and the failure number storage register 305.

In the case where the failed bit-cell position matches the value, the address comparator circuit 308 outputs the matching signal 309 at “High” level. In the case where the failed bit-cell position does not match the value, the address comparator circuit 308 outputs the matching signal 309 at “Low” level (e.g., logic “0”).

The failed bit-cell position storage register selector circuit 313 counts up the value of the failure number storage register 305 (the number of bit cell failures) in the case where the matching signal 309 is at “High” level and the shift enable of the corresponding enable register 307 is at “High” level.

In other words, in the case where the failed bit-cell position matches the value stored in the failed bit-cell position storage register 304 and data (failed bit-cell position) has been stored in the corresponding failed bit-cell position storage register 304, the failed bit-cell position storage register selector circuit 313 counts up the number of failures so as to correspond to the failed bit-cell position.

The failed bit-cell position is obtained from the address of a failed bit cell in the address holding register 312. As described above, the address is specified by the row address, the column address, and the I/O bit position. Furthermore, the failed bit-cell position is specified by the row address or the column address and the I/O bit position.

In the case where the matching signal 309 is at “Low” level, that is, the failed bit-cell position does not match the value stored in the failed bit-cell position storage register 304, the value of the failed bit-cell position storage register 304 is held.

The failure number storage register 305 can set any upper limit value. For example, in the case where the number of failures exceeds the set upper limit value, the failure number storage register 305 sets the failure overflow flag FOVF of the failure overflow flag register 306 at “High” level.

In the case where the test result flag 311 is set at “High” level and the matching signals 309 outputted from the address comparator circuits 308 are all set at “Low” level, the failed bit-cell position storage register selector circuit 313 selects one of the register groups with the shift enable at “Low” level, updates the shift enable of the enable register 307 of the register group to “High” level, stores the failed bit-cell position obtained from the address holding register 312 in the failed bit-cell position storage register 304, and stores “1” (counts up) for the value of the failure number storage register 305. In the case where the test result flag 311 is set at “High” and some of the matching signals 309 outputted from the respective address comparator circuits 308 are set at “High” level, the failed bit-cell position storage register selector circuit 313 selects one of the register groups when all the corresponding enable registers 307 are set at “Low” level. Further, the failed bit-cell position storage register selector circuit 313 updates the shift enable of the enable register 307 of the selected register group to “High” level, stores the failed bit-cell position obtained from the address holding register 312 in the failed bit-cell position storage register 304, and stores “1” (counts up) for the value of the failure number storage register 305.

As described above, the failure information table 302 stores a failed bit-cell position that is an address, in the column direction, of a bit cell identified as a failed bit cell in a BIST conducted in the column direction, stores the number of bit cell failures at the failed bit-cell position, and stores the failure overflow flag that indicates whether the number of failures exceeds the predetermined upper limit value or not.

Moreover, the failure information table 302 outputs the failed bit-cell position, the number of failures, and the failure overflow flag FOVF in each of the register groups 302a-1 to 302a-n to the identifying unit 1.

The identifying unit 1 identifies the failure type of the embedded memory based on the inputted test result flag 311, the failed bit-cell position, the number of failures, and the failure overflow flag FOVF.

For example, in the case where the failure overflow flag FOVF has a value of “1”, that is, the number of failed bit-cells exceeds the upper limit value at an address (a failed bit-cell position) in the column direction of the memory 112, the identifying unit 1 identifies the failure type as a column failure in which multiple failed bit cells are present in the column direction in the memory 112.

In the case where the values of the failure overflow flags FOVF are all “0” and the number of failures is at least one, the identifying unit 1 identifies the failure type as a bit failure in which failed bit cells are scattered in bits in the memory 112.

When the number of failures is “0”, the identifying unit 1 decides that no failures are present.

As described above, the semiconductor integrated circuit of the present embodiment can identify the failure type of the embedded memory.

### Second Embodiment

A second embodiment will describe a structural example in which the BIST circuit of the first embodiment further includes a configuration for outputting a table overflow flag indicating that failure data exceeds a data amount storable in a failure information table.

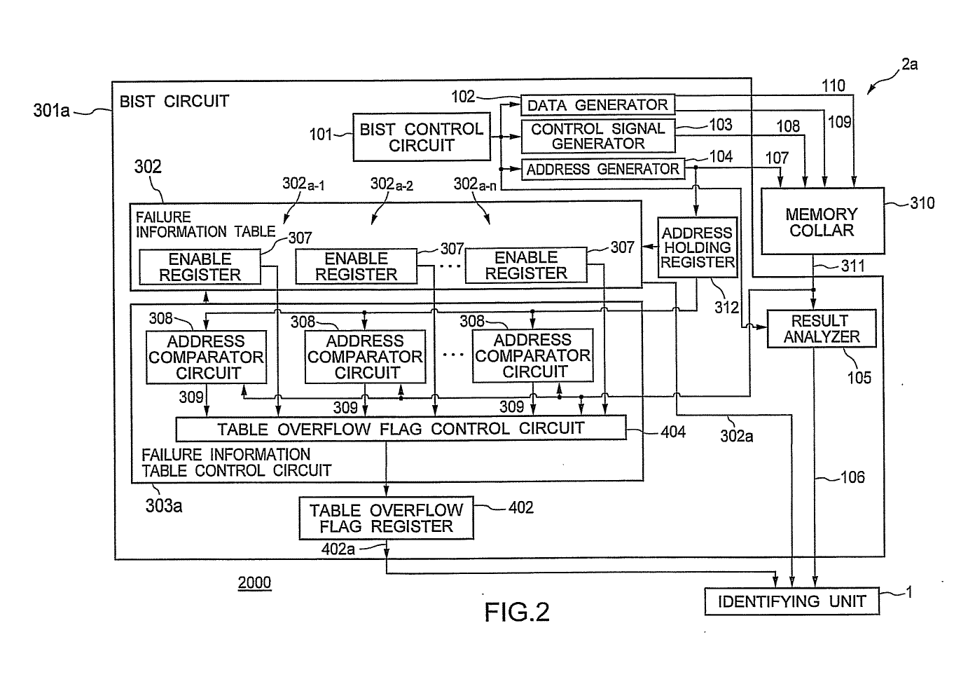

FIG. 2 shows an example of the configuration of a failure diagnosis system 2000 according to the second embodiment. In FIG. 2, the same reference numerals as in FIG. 1 indicate the same configurations as in the first embodiment. Some of the constituent elements of a failure information table 302 are omitted in FIG. 2 but the failure information table 302 is identical in configuration to that of FIG. 1. Moreover, in a failure information table control circuit 303a, the failed bit-cell position storage register selector circuit 313 included in the failure information table control circuit 303 of FIG. 1 is omitted.

As shown in FIG. 2, the failure diagnosis system 2000 includes an identifying unit 1 and a semiconductor integrated circuit 2a.

The semiconductor integrated circuit 2a includes a memory collar 310 and a BIST circuit 301a.

The BIST circuit 301a further includes a table overflow flag register 402 unlike in the BIST circuit 301 of the first embodiment.

The failure information table control circuit 303a further includes a table overflow flag control circuit 404 unlike in the failure information table control circuit 303 of the first embodiment.

In the same processing as in the first embodiment, in the case where a test result flag 311 is at “High” level, enable registers 307 for all n data sets have values at “High” level (e.g., logic “1”), and matching signals 309 all have values at “Low” level (e.g., logic “0”), the table overflow flag control circuit 404 cannot store detected failure data in the failure information table 302.

In other words, in the case where the number of addresses, in the column direction, of failed bit cells (column addresses and I/O bit positions) exceeds the capacity of the failure information table 302 (the number of failed bit-cell position storage registers 304) in the column direction of a memory 112, failure data cannot be additionally stored in the failure information table 302.

In this case, the table overflow flag control circuit 404 sets the value of the table overflow flag register 402 (table overflow flag 402a) at, for example, “High” level (logic “1”).

In the case where the number of addresses, in the column direction, of failed bit cells (column addresses and I/O bit positions) does not exceed the capacity of the failure information table 302 (the number of failed bit-cell position storage registers 304) in the column direction of the memory 112, the table overflow flag control circuit 404 holds the value of the table overflow flag register 402 (table overflow flag 402a) at, for example, “Low” level (logic “0”).

In this manner, the table overflow flag register 402 stores the table overflow flag indicating whether the number of failed bit-cell positions exceeds the capacity of the failure information table 302 or not.

The table overflow flag register 402 outputs the table overflow flag 402a to the identifying unit 1.

Other configurations and functions of the semiconductor integrated circuit 2a are similar to those of the semiconductor integrated circuit 2 of the first embodiment.

In other words, as in the first embodiment, the identifying unit 1 can identify the failure type of the embedded memory based on the test result flag 311, a failed bit-cell position, the number of failures, and a failure overflow flag FOVF from the semiconductor integrated circuit 2a.

Furthermore, the identifying unit 1 can identify the failure type of the embedded memory based on the table overflow flag 402a.

As described above, the semiconductor integrated circuit of the present embodiment can identify the failure type of the embedded memory.

### Third Embodiment

A third embodiment will describe a structural example in which the BIST circuit of the second embodiment further includes a configuration for switching the modes of a failure information table.

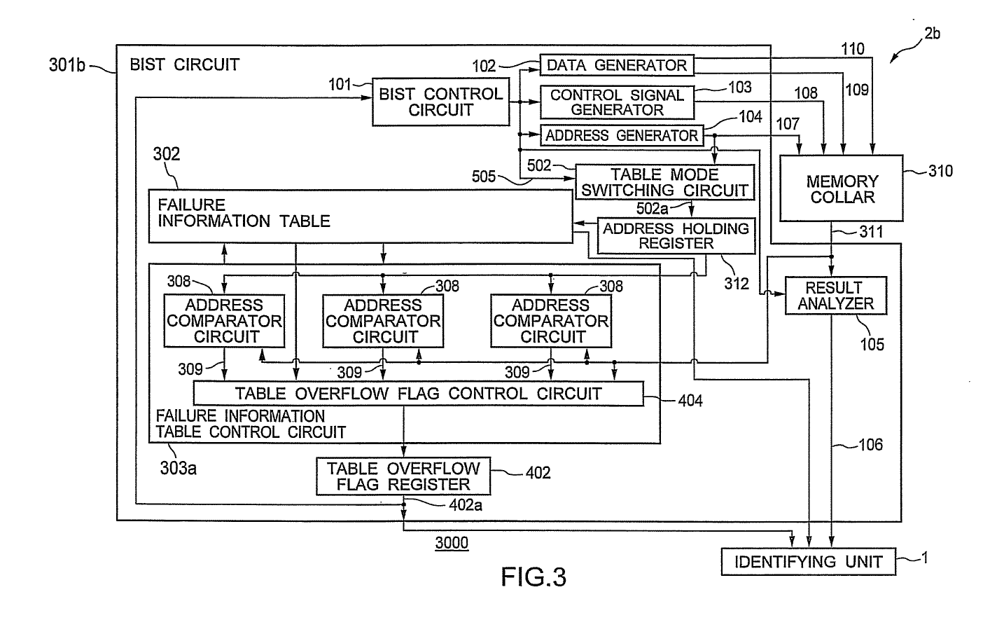

FIG. 3 shows an example of the configuration of a failure diagnosis system 3000 according to the third embodiment. In FIG. 3, the same reference numerals as in FIG. 2 indicate the same configurations as in the second embodiment. Some of the constituent elements of a failure information table 302 and a failure information table control circuit 303a are omitted in FIG. 3 but the failure information table 302 is identical in configuration to that of FIG. 1 and the failure information table control circuit 303a is identical to that of FIG. 2.

As shown in FIG. 3, the failure diagnosis system 3000 includes an identifying unit 1 and a semiconductor integrated circuit 2b.

Unlike the BIST circuit 301a of the second embodiment, a BIST circuit 301b further includes a table mode switching circuit 502 for switching the modes of the failure information table 302.

Moreover, a BIST control circuit 101 outputs a table mode switching signal 505 to the table mode switching circuit 502 based on a table overflow flag 402a to control switching of the modes.

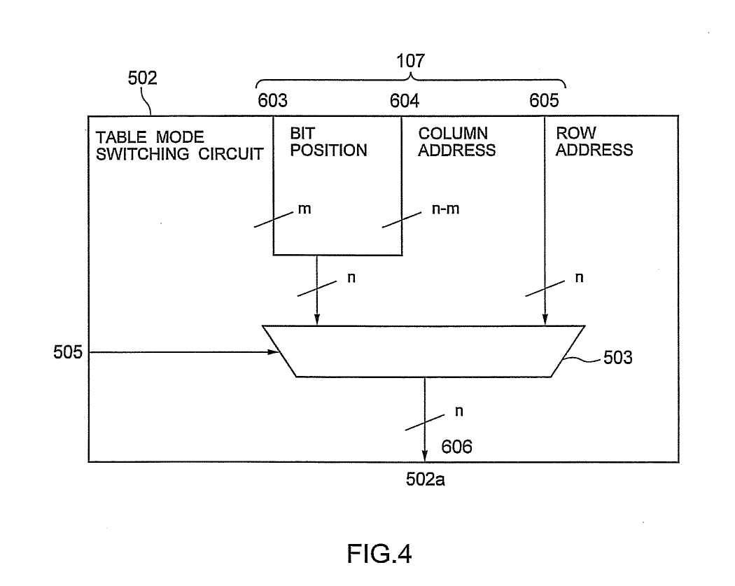

FIG. 4 shows an example of the configuration of the table mode switching circuit 502 in the BIST circuit 301b of FIG. 3.

As shown in FIG. 4, when the table mode switching signal 505 is at “Low” level (e.g., logic “0”), the table mode switching circuit 502 controls a multiplexer 503 to output an I/O bit position 603 and a column address 604, which have been inputted from an address generator 104, from an output part 606.

When the table mode switching signal 505 is at “High” level (e.g., logic “1”), the table mode switching circuit 502 controls the multiplexer 503 to output a row address 605 from the output part 606.

The size of the output part 606 is set larger than the total size of the I/O bit position 603 and the column address 604 and the size of the row address 605.

The following will describe an example of the switching operation of the table mode switching circuit 502.

First, the BIST control circuit 101 sets the table mode switching signal 505 at “Low” level. Thus the BIST circuit 301b conducts a BIST in a mode (first mode) of storing the I/O bit position 603 and the column address 604 in the failure information table 302.

After the first BIST, the BIST circuit 301b determines the value of a first table overflow flag TOVF[0].

For example, the BIST control circuit 301b switches the table mode switching signal to “High” level in the case where the first table overflow flag TOVF[0] is at “High” level (specifically, the number of addresses, in the column direction, of failed bit cells (determined by the column address and the I/O bit position) exceeds the capacity of the failure information table 302 in the column direction of the memory 112).

In the case where a BIST is conducted on a memory 112 in the row address direction, the failure information table 302 resets a failed bit-cell position, the number of failures, and a failure overflow flag that are stored for the BIST conducted in the column address direction.

Thus the BIST circuit 301b conducts the second BIST in a mode (second mode) of storing row addresses in the failure information table 302.

As described above, the BIST control circuit 301b conducts a BIST on the memory 112 in the column address direction, and then conducts a BIST on the memory 112 in the row address direction in the case where it is decided that the number of failed bit-cell positions exceeds the capacity of the failure information table 302 based on the first table overflow flag TOVF[0].

After that, the failure information table 302 stores a failed bit-cell position that is the address, in the row address direction, of a bit cell identified as a failed bit cell in a BIST conducted in the row address direction. The failure information table 302 further stores the number of bit cell failures at the failed bit-cell position and the failure overflow flag indicating whether the number of failures exceeds the upper limit value or not.

The third embodiment is different only in that an input value is changed by the table mode switching circuit 502. Other configurations are not different from those of the foregoing embodiments.

Thus in the BIST circuit 301b, the failure information table 302 does not have to be provided for each of the test modes, so that the failure information table 302 can be shared between the test modes.

In the case where the number of addresses, in the row direction, of failures detected in the row address storage mode exceeds the capacity of the failure information table 302, a second table overflow flag TOVF[1] is set at “High” level.

After all of the tests are conducted, the BIST circuit 301b serially outputs the information of the table.

The BIST circuit 301b may output the values of the failure information table with test results after the completion of the first test.

As described above, in the present embodiment, a BIST is first conducted in the mode of storing the I/O bit position 603 and the column address 604.

In the case where a BIST is first conducted in the row address storage mode and the first table overflow flag TOVF[0] is at “High” level, the BIST control circuit 101 may set the table mode switching signal 505 at “High” level to switch the mode of the failure information table 302.

Other configurations and functions of the semiconductor integrated circuit 2b are similar to those of the semiconductor integrated circuit 2a of the second embodiment.

Specifically, as in the second embodiment, the identifying unit 1 can identify the failure type of the embedded memory based on the test result flag 311, the failed bit-cell position, the number of failures, and a failure overflow flag FOVF, and the table overflow flag 402a from the semiconductor integrated circuit 2b.

As described above, the semiconductor integrated circuit of the present embodiment can identify the failure type of the embedded memory.

### Fourth Embodiment

A fourth embodiment will describe an example of a failure diagnosis method in which the failure diagnosis system of the third embodiment identifies the failure type of memory.

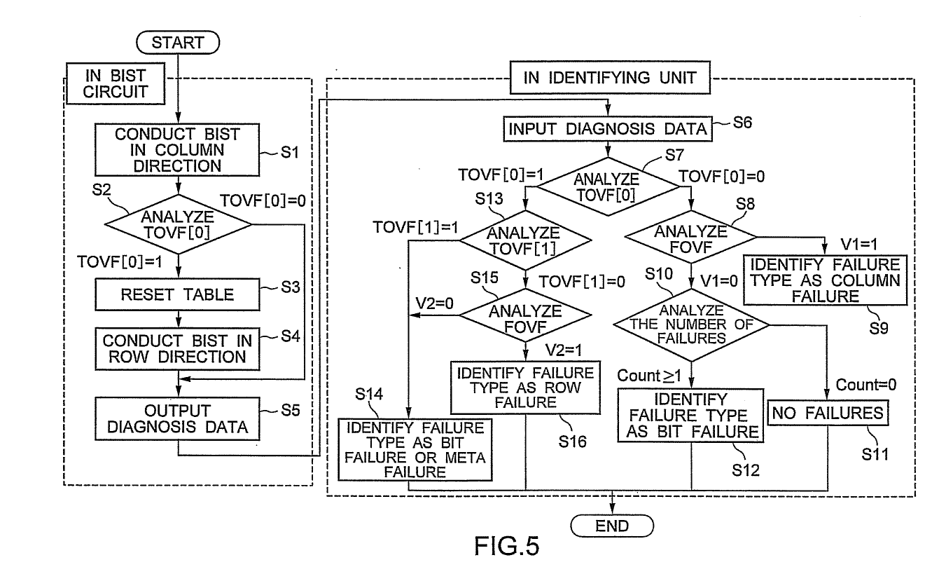

FIG. 5 is a flowchart showing an example of the flow of the failure diagnosis method according to the fourth embodiment.

As shown in FIG. 5, first, a BIST circuit 301b conducts a BIST on a memory 112 in the column direction (step S1).

Next, a BIST control circuit 101 of the BIST circuit 301b analyzes the value of a first table overflow flag TOVF[0] (step S2).

In the case where the first table overflow flag TOVF[0] is at “High” level (logic “1”) (specifically, the number of addresses of failed bit cells (failed bit-cell positions) in the column direction exceeds the capacity of the failure information table 302 in the column direction of the memory 112), the BIST circuit 301b resets the values of the registers of a failure information table 302 (step S3).

The BIST control circuit 101 controls a table mode switching circuit 502 in response to the first table overflow flag TOVF[0] at “High” level to switch the failure information table 302 from a mode of storing an I/O bit position and a column address (first mode) to a mode of storing a row address (second mode). Thus the BIST circuit 301b conducts a BIST on the memory 112 in the row direction (step S4).

The BIST circuit 301b outputs diagnosis data obtained by the two BISTs (a BIST result 106, a failure overflow flag FOVF, first and second table overflow flags TOVF[0], TOVF[1](402a)) to an identifying unit 1 (step S5).

In step S2, in the case where the first table overflow flag TOVF[0] is at “Low” level (logic “0”) (specifically, the number of addresses of failed bit cells (failed bit-cell positions) in the column direction does not exceed the capacity of the failure information table 302 in the column direction of the memory 112), the process advances to step S5. The BIST circuit 301b outputs diagnosis data (the BIST result 106, the failure overflow flag FOVF, the first and second table overflow flags TOVF[0], TOVF[1](402a)) obtained by the first BIST (only in the column direction) to the identifying unit 1.

The following steps are performed by the identifying unit 1.

Diagnosis data obtained by the BIST performed by the BIST circuit 301b is inputted to the identifying unit 1 (step S6).

Next, the identifying unit 1 analyzes the value of the first table overflow flag TOVF[0] based on the diagnosis data (step S7).

For example, in the case where the value of the first table overflow flag TOVF[0] is “0” (specifically, the number of addresses of failed bit cells (failed bit-cell positions) in the column direction does not exceed the capacity of the failure information table 302 (the number of failed bit-cell position storage registers 304) in the column direction of the memory 112), the identifying unit 1 analyzes the failure overflow flag FOVF. In other words, the identifying unit 1 calculates the logical sum of the values of the n failure overflow flags FOVF of the failure information table 302 (Step S8).

In the case where a calculated value (logical sum) V1 is “1” (specifically, the number of failed bit cells exceeds the upper limit value at an address (failed bit-cell position) in the column direction of the memory 112), the identifying unit 1 identifies the failure type as a column failure in which multiple failed bit cells are present in the column direction in the memory 112 (step S9).

In the case where the calculated value (logical sum) V1 is “0” (specifically, the number of failed bit cells does not exceed the upper limit value at an address (a failed bit-cell position) in the column direction of the memory 112), the identifying unit 1 analyzes values (the number of failures) stored in failure number storage registers 305 (step S10).

In the case where a value Count of the first failure number storage register is “0” (specifically, failed bit cells are not present in the column direction in the memory 112), the identifying unit 1 decides that the memory 112 has no failures (step S11).

In the case where the value Count of the first failure number storage register is at least “1” (specifically, the number of failed bit cells does not exceed the upper limit value in the column direction in the memory 112), the identifying unit 1 identifies the failure type as a bit failure in which failed bit cells are scattered in bits in the memory 112 (step S12).

In step S7, in the case where the first table overflow flag TOVF[0] has a value of “1” (specifically, the number of addresses of failed bit cells (failed bit-cell positions) in the column direction exceeds the capacity of the failure information table 302 (the number of failed bit-cell position storage registers 304) in the column direction of the memory 112), the identifying unit 1 determines the value of a second table overflow flag TOVF[1] (step S13).

In the case where the value of the second table overflow flag TOVF[1] is “1” (specifically, the number of addresses of failed bit cells in the row direction (row addresses) exceeds the capacity of the failure information table 302 (the number of failed bit-cell position storage registers 304) in the row direction of the memory 112), the identifying unit 1 identifies the failure type as a bit failure or a meta failure in which failed bit cells are scattered over the memory 112 (step S14).

In the case where the value of the second table overflow flag TOVF[1] is “0” (specifically, the number of addresses of failed bit cells (failed bit-cell positions) in the row direction does not exceed the capacity of the failure information table 302 (the number of failed bit-cell position storage registers 304) in the row direction of the memory 112), the identifying unit 1 calculates a logical sum V2 of the values of the n failure overflow flags FOVF of the failure information table 302 (step S15).

In the case where a calculated value (logical sum) V2 is “1”, the identifying unit 1 identifies the failure type as a row failure in which failed bit cells are present in the row direction in the memory 112 (step S16).

In the case where the calculated value (logical sum) V2 is “0”, the process advances to step S14 in which the identifying unit 1 identifies the failure type as a bit failure or a meta failure.

The failure type of the memory 112 can be identified by the above steps.

Additionally, the accuracy of identification of the failure type of the memory 112 in the identifying unit 1 can be increased with the number of elements in the information table 302 of the first embodiment and the upper limit value of the failure number storage register.

As described above, the failure diagnosis method of the present embodiment can identify the failure type of the embedded memory.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a memory containing multiple memory bits that store predetermined data placed in a first address direction and a second address direction; and
a BIST (Built-in Self-Test) circuit that diagnoses a failure of the memory,
wherein the BIST circuit comprising:
a BIST control circuit that controls a BIST on the memory;
a failure information table storing: a failed bit-cell position that is an address of a bit cell identified in the first address direction as a failed bit cell by the BIST conducted in the first address direction; the number of bit cell failures at the failed bit-cell position; and a failure overflow flag indicating whether the number of failures exceeds a predetermined upper value or not; and
a result analyzer that outputs a BIST result obtained by the BIST on the memory.

2. The semiconductor integrated circuit of claim 1, wherein the BIST circuit further comprises a table overflow flag register that stores a table overflow flag indicating whether or not the number of failed bit-cell positions exceeds a capacity of the failure information table.

3. The semiconductor integrated circuit of claim 2, wherein after the BIST on the memory in the first address direction, the BIST control circuit conducts a BIST on the memory in the second address direction in the case where it is decided that the number of failed bit-cell positions exceeds the capacity of the failure information table based on the table overflow flag.

4. The semiconductor integrated circuit of claim 3, wherein the failure information table stores: a failed bit-cell position that is an address of a bit cell identified in the second address direction as a failed bit cell by the BIST conducted in the second address direction; the number of bit cell failures at the failed bit-cell position; and a failure overflow flag indicating whether the number of failures exceeds the upper value or not.

5. The semiconductor integrated circuit of claim 1, wherein the failure information table includes multiple registers, each storing the failed bit-cell position, the number of failures, and the failure overflow flag.

6. The semiconductor integrated circuit of claim 2, wherein the failure information table includes multiple registers, each storing the failed bit-cell position, the number of failures, and the failure overflow flag.

7. The semiconductor integrated circuit of claim 3, wherein the failure information table includes multiple registers, each storing the failed bit-cell position, the number of failures, and the failure overflow flag.

8. The semiconductor integrated circuit of claim 4, wherein the failure information table includes multiple registers, each storing the failed bit-cell position, the number of failures, and the failure overflow flag.

9. A failure diagnosis system comprising:
a semiconductor integrated circuit; and
a failure type determination unit that determines a failure type of a memory,
wherein the semiconductor integrated circuit comprising:
a memory containing multiple memory bits that store predetermined data placed in a first address direction and a second address direction; and
a BIST (Built-in Self-Test) circuit that diagnoses a failure of the memory,
wherein the BIST circuit comprising:
a BIST control circuit that controls a BIST on the memory;
a failure information table storing: a failed bit-cell position that is an address of a bit cell identified in the first address direction as a failed bit cell by the BIST conducted in the first address direction; the number of bit cell failures at the failed bit-cell position; and a failure overflow flag indicating whether the number of failures exceeds a predetermined upper value or not; and
a result analyzer that outputs a BIST result obtained by the BIST on the memory, and
wherein the failure type determination unit determines the failure type of the memory based on the number of failures and a failure overflow flag.

10. The failure diagnosis system of claim 9, wherein the BIST circuit further comprises a table overflow flag register that stores a table overflow flag indicating whether or not the number of failed bit-cell positions exceeds a capacity of the failure information table.

11. The failure diagnosis system of claim 10, wherein after the BIST on the memory in the first address direction, the BIST control circuit conducts a BIST on the memory in the second address direction in the case where it is decided that the number of failed bit-cell positions exceeds the capacity of the failure information table based on the table overflow flag.

12. The failure diagnosis system of claim 11, wherein the failure information table stores: a failed bit-cell position that is an address of a bit cell identified in the second address direction as a failed bit cell by the BIST conducted in the second address direction; the number of bit cell failures at the failed bit-cell position; and a failure overflow flag indicating whether the number of failures exceeds the upper value or not.

13. The failure diagnosis system of claim 9, wherein the failure information table includes multiple registers, each storing the failed bit-cell position, the number of failures, and the failure overflow flag.

14. The failure diagnosis system of claim 10, wherein the failure information table includes multiple registers, each storing the failed bit-cell position, the number of failures, and the failure overflow flag.

15. The failure diagnosis system of claim 11, wherein the failure information table includes multiple registers, each storing the failed bit-cell position, the number of failures, and the failure overflow flag.

16. The failure diagnosis system of claim 12, wherein the failure information table includes multiple registers, each storing the failed bit-cell position, the number of failures, and the failure overflow flag.

17. A failure diagnosis method for a semiconductor circuit, the semiconductor integrated circuit comprising: a memory containing multiple memory bits that store data placed in a first address direction and a second address direction; and a BIST (Built-in Self-Test) circuit that diagnoses a failure of the memory, wherein the BIST circuit comprising: a BIST control circuit that controls a BIST on the memory; a failure information table storing: a failed bit-cell position that is an address of a bit cell identified in the first address direction as a failed bit cell by the BIST conducted in the first address direction; the number of bit cell failures at the failed bit-cell position; and a failure overflow flag indicating whether the number of failures exceeds a predetermined upper value or not, the method comprising:
identifying the failure type of the memory based on the number of failures and a failure overflow flag.

18. The failure diagnosis system of claim 17, wherein the BIST circuit further comprises a table overflow flag register that stores a table overflow flag indicating whether or not the number of failed bit-cell positions exceeds a capacity of the failure information table.

19. The failure diagnosis method of claim 18, wherein after the BIST on the memory in the first address direction, the BIST control circuit conducts a BIST on the memory in the second address direction in the case where it is decided that the number of failed bit-cell positions exceeds the capacity of the failure information table based on the table overflow flag.

20. The failure diagnosis method of claim 19, wherein the failure information table stores: a failed bit-cell position that is an address of a bit cell identified in the second address direction as a failed bit cell by the BIST conducted in the second address direction; the number of bit cell failures at the failed bit-cell position; and a failure overflow flag indicating whether the number of failures exceeds the upper value or not.
